(19) United States
(12) Patent Application Publication
(10) Pub. No.: US 2019/0051488 A1
(43) Pub. Date: Feb. 14, 2019

(54) Ion Implantation Apparatus and Method of Manufacturing Semiconductor Devices

(71) Applicant: Infineon Technologies AG, Neubiberg (DE)

(72) Inventors: Werner Schustereder, Villach (AT); Moriz Jelinek, Villach (AT); Hans-Joachim Schulze, Taufkirchen (DE)

(21) Appl. No.: 16/057,014

(22) Filed: Aug. 7, 2018

(30) Foreign Application Priority Data
Aug. 8, 2017 (DE) 102017117999.2

(51) Int. Cl. H01J 37/20; H01J 37/317; H01J 37/147; H01L 21/265; H01L 21/04; H01L 21/266; H01L 21/225; C23C 14/48; C23C 14/04; C23C 14/54

(52) U.S. Cl. CPC H01J 37/20; H01L 29/7395; H01J 37/1474; H01L 21/2652; H01L 21/047; H01L 21/0465; H01L 21/26533; H01L 21/266; H01L 21/26586; H01L 21/2253; C23C 14/48; C23C 14/042; C23C 14/54; H01J 2237/20207; H01J 2237/20285; H01J 37/3171

(57) ABSTRACT

An implantation apparatus includes a scanning assembly that effects a relative movement between an ion beam and a semiconductor substrate along a first scan direction and along a second scan direction orthogonal to the first scan direction. A tilt assembly changes a tilt angle θ between a beam axis of the ion beam and a normal to a main surface of the semiconductor substrate from a first tilt angle θ1 to a second tilt angle θ2, wherein an angular span Δθ between the first tilt angle θ1 and the second tilt angle θ2 is at least 5°. A control unit controls the tilt assembly to continuously change the tilt angle θ during the relative movement between the ion beam and the semiconductor substrate.

### BACKGROUND

Some parameters of semiconductor devices can be linked to properties of vertical dopant profiles. For example, vertical power semiconductor devices that control a load current flow between a first load electrode at a front side and a second load electrode on the back of a semiconductor die include doped regions such as drift zone, compensation structures, buffer layers and field stop layers with specific vertical dopant profiles, wherein parameters of the vertical dopant profiles of the concerned layers such as uniformity, smoothness and undulation may have significant impact on device parameters. Compared to the introduction of dopants by epitaxy or deposition., ion implantation allows precisely monitoring both total dose and dose rate. Ion implantation typically leads to a Gaussian-like distribution of the dopants around an end-off-range-peak which distance to a substrate surface is a function of the acceleration energy of the implanted ions. In semiconductor crystals with high diffusion coefficients for the dopant ions, a heat treatment diffuses the implanted dopants and spreads the vertical implant profiles. In semiconductor crystals with low diffusion coefficients for the dopant ions, or if the maximum allowed thermal budget for diffusion is limited, the ion implantation process may be adapted by several means for spreading the vertical dopant profile.

There is a need for a doping method and an apparatus that provide more flexibility at low process costs as regards the shape of the vertical dopant profiles.

### SUMMARY

The present disclosure relates to an implantation apparatus that includes a scanning assembly, a tilt assembly and a control unit. The scanning assembly effects a relative movement between an ion beam and a semiconductor substrate along a first horizontal direction and along a second horizontal direction orthogonal to the first horizontal direction. The tilt assembly is configured to change a tilt angle θ between a beam axis of the ion beam and a normal to a main surface of the semiconductor substrate from a first angle θ1 to a second angle θ2, wherein an angular span Δθ between the first tilt angle θ1 and the tilt second angle θ2 is at least 5°. The control unit is configured to control the tilt assembly to continuously change the tilt angle θ during the relative movement between ion beam and semiconductor substrate.

The present disclosure further relates to an ion implantation method. An ion beam onto a main surface of a semiconductor substrate, wherein a relative movement, between the semiconductor substrate and the ion beam results in that the ion beam scans the main surface. During the relative movement, a tilt angle θ between a beam axis of the ion beam and a normal to the main surface continuously changes from a first tilt angle θ1 to a second tilt angle θ2, wherein an angular span Δθ between the first tilt angle θ1 and the second tilt angle θ2 is at least 5°.

The present disclosure further relates to another implantation apparatus that includes a scanning assembly, a tilt assembly, and a control unit. The scanning assembly effects a relative movement between an ion beam and a semiconductor substrate along a first scan direction and along a second scan direction orthogonal to the first scan direction. The tilt assembly changes a tilt angle θ between a beam axis of the ion beam and a normal to a main surface of the semiconductor. substrate from a first tilt angle θ1 to a second tilt angle θ2, wherein an angular span Δθ between the first tilt angle θ1 and the second tilt angle θ2 is at least 5°. The control unit controls the tilt assembly and the scanning assembly during a single ion implantation process to perform successive sweeps along the second scan direction (at different tilt angles.

Further embodiments are described in the dependent claims. Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the present embodiments and are incorporated in and constitute a part of this specification. The drawings illustrate the present embodiments and together with the description serve to explain principles of the embodiments. Further embodiments and intended advantages will be readily appreciated as they become better understood by reference to the following detailed description.

FIG. 1 is a schematic block diagram of an implantation apparatus with a tilt assembly changing a tilt angle between a main surface of a semiconductor substrate and an ion beam scanned over the main surface according to an embodiment related to a continuous sweep of the tilt angle during scanning.

FIG. 2 is a schematic block diagram of a scanning assembly according to an embodiment related to electrostatic beam deflection in two orthogonal directions.

FIG. 3 is a schematic block diagram of a scanning assembly according to an embodiment, combining beam deflection with a mechanical scan.

FIG. 4 is a simplified flowchart of an implantation method according to an embodiment based on an implantation apparatus as illustrated in FIG. 1.

FIG. 5A is a diagram plotting the projected range of protons in a silicon crystal as a function of a tilt angle for discussing effects of the embodiment.

FIG. 5B is a diagram plotting the projected range of phosphorus ions in a silicon crystal as a function of a tilt angle for discussing effects of the embodiment.

FIG. 5C is a diagram plotting the projected range of boron ions in a silicon crystal as a function of a tilt angle for discussing effects of the embodiment.

FIG. 5D is a diagram plotting the projected range of nitrogen ions in a silicon carbide crystal as a function of a tilt angle for discussing effects of the embodiment.

FIG. 6A is a schematic block diagram of an implantation apparatus with a tilt assembly changing a tilt angle between a main surface of a semiconductor substrate and an ion beam scanned over the main surface according to an embodiment related to a stepwise change of the tilt angle between successive scans along a first scan direction.

FIG. 6B is a schematic time chart for tilt angle and deflection along a first scan direction for the ion beam of the implantation apparatus of FIG. 1.

FIG. 7 is a simplified flow chart of an implantation method according to an embodiment related to an implantation apparatus as illustrated in FIG. 6A.

FIG. 8A is a schematic vertical cross-sectional view of a portion of a semiconductor substrate for illustrating a method of manufacturing semiconductor devices that includes changing an implant angle during scanning according to an embodiment related to the formation of drift layers, after forming a first epitaxial layer.

FIG. 8B is a schematic vertical cross-sectional view of the semiconductor substrate portion of FIG. 8A during ion implantation at changing implant angle.

FIG. 8C is a schematic diagram illustrating a vertical dopant profile along line C-C in FIG. 8B after ion implantation.

FIG. 9A is a schematic vertical cross-sectional view of a portion of a semiconductor substrate for illustrating a method of manufacturing semiconductor devices that includes changing an implant angle during scanning according to an embodiment related to the formation of thick drift layers, after a first ion implantation and after forming a second epitaxial layer.

FIG. 9B is a schematic vertical cross-sectional view of the semiconductor substrate portion of FIG. 9A during a second ion implantation at changing implant angle.

FIG. 9C is a schematic diagram illustrating a vertical dopant profile along line C-C in FIG. 9B after the second ion implantation,

FIG. 10A is a schematic vertical cross-sectional view of a portion of a semiconductor substrate for illustrating a method of manufacturing semiconductor devices related to drift layers formed at a small distance to a main surface, after forming an absorber layer.

FIG. 10B is a schematic vertical cross-sectional view of the semiconductor substrate portion of FIG. 10A during ion implantation through the absorber layer.

FIG. 10C is a schematic diagram illustrating a vertical dopant profile along line C-C in FIG. 10B after ion implantation.

FIG. 11A is a schematic vertical cross-sectional view of a portion of a semiconductor substrate for illustrating a method of manufacturing semiconductor devices that includes chancing an implant angle during scanning according to an embodiment related to the combined formation of a lightly doped drift layer adjoining a more heavily doped field stop or charge compensation layer, after forming a first epitaxial layer.

FIG. 11B is a schematic vertical cross-sectional view of the semiconductor substrate portion of FIG. 11A during ion implantation at changing implant angle and changing implant dose.

FIG. 11C is a schematic diagram illustrating a vertical dopant profile along line C-C in FIG. 11B after ion implantation.

FIG. 12A is a schematic cross-sectional view of a semiconductor device including a drift zone with a doping defined by ion implantation at changing implant angle according to an embodiment related to semiconductor diodes.

FIG. 12B is a schematic cross-sectional view of a semiconductor device including a drift zone with a doping defined by ion implantation at changing implant angle according to an embodiment related to semiconductor switches.

FIG. 12C is a schematic diagram illustrating a section of a vertical dopant profile of the semiconductor devices of FIG. 12A or FIG. 12B along lines C-C according to an embodiment related to a field stop zone formed by proton implantation at continuously or stepwise changing implant angle.

FIG. 13 is a schematic vertical cross-sectional view of a portion of a semiconductor substrate for illustrating a method of manufacturing semiconductor devices related to formation of a deep emitter layer, during ion implantation at changing implant angle.

FIG. 14A is a schematic vertical cross-sectional view of a semiconductor device obtained from the semiconductor substrate of FIG. 13.

FIG. 14B is a schematic diagram illustrating a vertical dopant profile alone; line B-B in FIG. 14A.

FIG. 15A is a schematic vertical cross-sectional view of a portion of a semiconductor substrate for illustrating a method of manufacturing semiconductor devices according to an embodiment related to superjunction devices during ion implantation of acceptors at changing implant angle.

FIG. 15B is a schematic vertical cross-sectional view of the semiconductor substrate portion of FIG. 15A during ion implantation of donors at changing implant angle.

FIG. 15C is a schematic vertical cross-sectional view of the semiconductor substrate portion of FIG. 15B, after forming trenches extending into the semiconductor substrate portion of FIG. 15B.

FIG. 15D is a schematic vertical cross-sectional view of the semiconductor substrate portion of FIG. 15C, after filling the trenches with semiconductor material.

FIG. 15E is a schematic vertical cross-sectional view of the semiconductor substrate portion of FIG. 15D, after a heating treatment.

FIG. 16A is a schematic vertical cross-sectional view of a portion of a semiconductor device according to an embodiment related to a super junction structure defined by ion Implantation at changing implant angle.

FIG. 16B is a schematic horizontal dopant profile along line B-B of FIG. 16A.

FIG. 16C is a portion of a schematic vertical dopant profile along line C-C of FIG. 16A.

FIG. 16D is a portion of a schematic vertical dopant profile along line D-D of FIG. 16A.

FIG. 17A is a schematic vertical cross-sectional view of a portion of a semiconductor substrate for illustrating a method of manufacturing semiconductor devices according to an embodiment related to formation of a germanium layer on a silicon base, during implantation of germanium at changing implant angle.

FIG. 17B is a schematic diagram illustrating a vertical germanium concentration profile along line B-B of FIG. 17A.

FIG. 18A is a schematic vertical cross-sectional view of a portion of a semiconductor substrate for illustrating a method of manufacturing semiconductor devices according to another embodiment related to the formation of a germanium layer on a silicon base, during implantation of germanium at changing implant angle.

FIG. 18B is a schematic diagram illustrating a vertical germanium concentration profile along line B-B of FIG. 18A.

FIG. 19 is a schematic vertical cross-sectional view of a portion of a semiconductor device according to an embodiment related to a stress-relaxation layer defined by ion implantation at changing implant angle.

FIG. 20A is a schematic plan view of a portion of a semiconductor substrate for illustrating a method of manufacturing semiconductor devices according to an embodiment related to formation of a buried oxide layer, after forming an implant mask.

FIG. 20B is a schematic vertical cross-sectional view of the semiconductor substrate portion of FIG. 20A, during implant of oxygen ions.

FIG. 20C is a schematic vertical cross-sectional view of the semiconductor substrate portion of FIG. 20B, after removal of the oxygen implant mask.

FIG. 20D is a schematic vertical cross-sectional view of the semiconductor substrate portion of FIG. 20C, after forming an epitaxial layer.

FIG. 20E is a schematic plan view of a portion of a semiconductor substrate according to an embodiment using a grid-like mask opening.

### DETAILED DESCRIPTION

In the following detailed description, reference is made to the accompanying drawings, which form a part hereof and in which are shown by way of illustrations specific embodiments in which the embodiments may be practiced. It is to be understood that other embodiments may be utilized and structural or logical changes may be made without departing from the scope of the present disclosure. For example, features illustrated or described for one embodiment can be used on or in conjunction with other embodiments to yield yet a further embodiment. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude additional elements or features. The articles “a”, “an” and “the” are intended to include the plural as well as the singular, unless the context clearly indicates otherwise.

The term “electrically connected” describes a permanent low-resistive connection between electrically connected elements, for example a direct contact between the concerned elements or a low-resistive connection via a metal and/or heavily doped semiconductor material. The term “electrically coupled” includes that one or more intervening element(s) adapted for signal transmission may be between the electrically coupled elements, for example, elements that are controllable to temporarily provide a low-resistive connection in a first state and a high-resistive electric decoupling in a second state.

The Figures illustrate relative doping concentrations by indicating “−” or “+” next to the doping type “n” or “p”. For example, “n−” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations. The scanning assembly and scanning method embodiments described herein pertain to moving an ion beam along defined directions with respect to a semiconductor substrate, and not to reading or analyzing techniques using an ion beam.

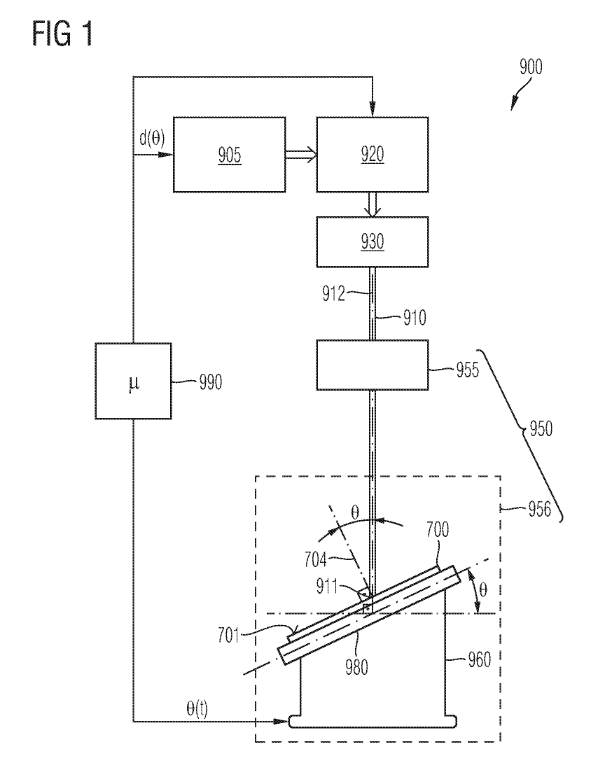

FIG. 1 shows an ion implantation apparatus 900 including an ion source 905 generating and emitting ions, for example, protons or ions with an atomic number greater 4, for example ions of nitrogen, aluminum, boron, phosphorus, arsenic, sulfur, selenium, germanium, or oxygen. An acceleration unit 920 may accelerate a selected type of ions and may filter out others. A collimator unit 930 may align the directions of motion of the ions in a direction parallel to a beam axis 912 and may direct a collimated ion beam 910 onto a semiconductor substrate 700, which may be temporarily fixed, e.g. electrostatically chucked onto a substrate holder 980. In a plane orthogonal to the beam axis 912 an ion distribution in the collimated ion beam 910 may be point-symmetric to a beam center.

A cross-sectional area of the ion beam. 910 may be in the order from few hundred square micrometers to few square centimeters. A scanning assembly 950 scans the ion beam 910 along a beam track 911 over a main surface 701 of the semiconductor substrate 700 to distribute the ions uniformly across the semiconductor substrate 700. The beam track 911 may include straight sections, may form circles or may form a spiral.

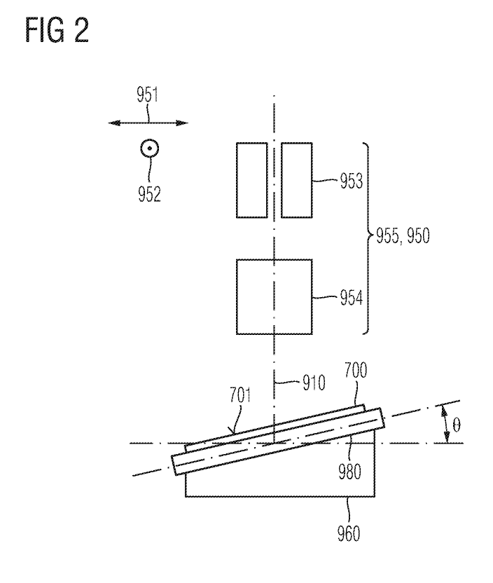

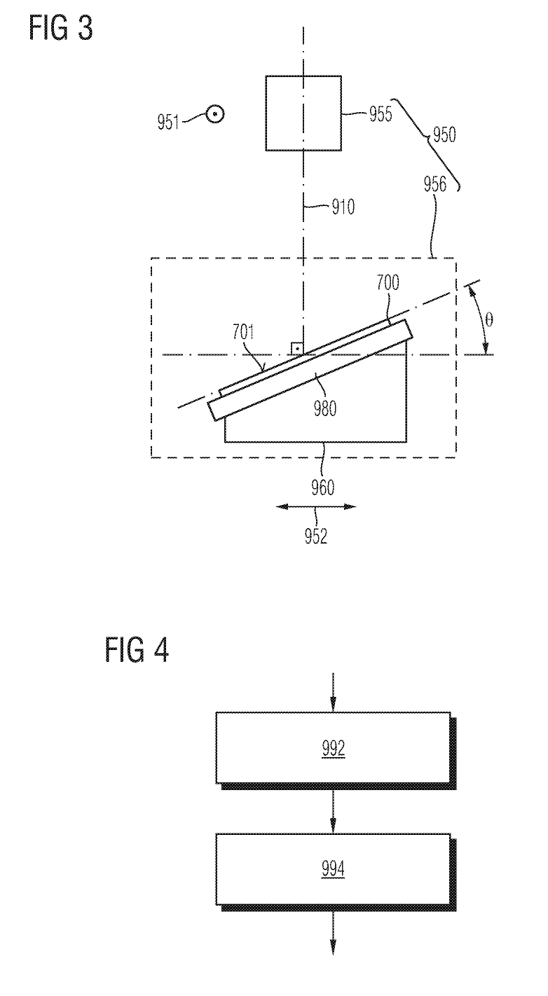

The scanning assembly 950 may control the scan by electrostatic fields, for example by a deflection unit 955, by mechanical movement of the substrate holder 980, for example by a stage assembly 956, or by a combination of both, wherein the scanning assembly 950 controls a relative movement between the ion beam 910 and the semiconductor substrate 700 on the basis of two orthogonal scan directions, which may be two linear directions or one rotational and one radial direction. A more detailed illustration and description of the scanning assembly 950 of FIG. 1 that is based on electrostatic field scanning along the two scan directions is illustrated in FIG. 2. In this case, a typical scan frequency along both scan directions is in the range of kHz. A deflection pattern may be chosen for optimal uniformity and scanning speed. By way of example, a deflection pattern may include up- and down-sweeps in a first scan direction. At each end point in the first direction the position in the second direction is incremented. When the end point in the second direction reached a shift in the second direction may be applied. Then, this basic pattern is reversed by moving up and down in the first direction and decrementing the position in the second direction. Thus, a scanning frequency along the first direction is larger than in the second direction depending on a number of increments of one sweep in the second direction. A more detailed illustration and description of the scanning assembly 950 of FIG. 1 that is based on a combination of electrostatic field scanning and mechanical scanning is illustrated in FIG. 3. In this case, a typical scan frequency of electrostatic field scanning along a first scan direction is in the range of kHz and a typical scan speed of mechanical scanning along a second scan direction is in the range of cm/s.

The ion implantation apparatus 900 further includes a tilt assembly 960 that changes a tilt, angle θ between a normal 704 to the main surface 701 and the beam axis 712 of the ion beam 910 between a first tilt angle θ1 and a second tilt angle during a single ion implantation process. A single ion implantation process is an ion implantation process that is based on a single implant recipe and is not interrupted by a tuning period for changing the implant recipe, for example. Thus, tilt angle change is part of the single implant recipe. An angular span Δθ between the first tilt angle θ1 and the second tilt angle θ2 is at least 5°, for example, 45°. The first tilt angle θ1 and the second tilt angle θ2 may be symmetric to each other with respect to the beam axis 912, i.e. θ2=−θ1. According to another embodiment, the first tilt angle θ1 and the second tilt angle θ2 may be asymmetric with respect to the beam axis 912, e.g., θ1=0°.

A control unit 990 may control the scanning assembly 950 and the tilt assembly 960 such that a change of the tilt angle θ is synchronized with at least one of the scans along the first and second scan directions.

Within the semiconductor substrate 700 the implanted ions come to rest over an area around a projected range and fall off in density on both sides of the projected range along a vertical direction orthogonal to the main surface 701. The projected range of the implanted ions decreases with increasing tilt angle θ such that a continuous sweep of the tilt angle θ results in a continuous sweep of the projected range in the semiconductor substrate 700 along a vertical direction orthogonal to the main surface 701.

The continuous change of the tilt angle θ during the scans of a single implant recipe improves control of vertical dopant profiles and provides a further degree of freedom for defining vertical dopant profiles. For example, in semiconductor substrates 700 with comparatively high diffusion coefficients the continuous change of the tilt angle θ reduces a thermal budget for expanding and smoothing vertical dopants by diffusion. For semiconductor substrates 700 with low diffusion coefficients, the continuous change of the tilt angle θ may replace elaborate alternatives. The tilt angle defines the current implant angle.

Synchronization of the change of the tilt angle θ with at least one of the scans, for example the scan having the slower scan speed may improve uniformity of the implant profile across the semiconductor substrate 700.

In addition, the control unit 990 may control the dose D(t) of the ion beam 910 as a function of the tilt angle θ. For example, an increase of the dose D(t) may compensate for a dose decrease resulting from that with increasing deviation of the tilt angle θ from 0° the ion beam 910 distributes across a greater partial area of the main surface 701.

Suitable variation of tilt angle θ and dose D(θ) results in improved adjustment of vertical dopant profiles to application specific features. For example, an implantation process with continuously changing implant angle may replace less precise epitaxy processes for forming comparatively thick uniformly doped layers with a thickness of more than 1 μm.

Transitions between vertically stacked layers of different dopant concentration may be defined smoother or sharper than by conventional methods. Compared to methods smoothing dopant profiles by diffusion, the tilted implant at continuously sweeping implant angle may get along with a lower temperature budget applied after the implant.

According to another embodiment, the control unit 990 provides a constant acceleration energy, wherein an implant with changing tilt angle θ during a single ion implantation process may achieve a result similar to processing several implant recipes, i.e. several ion implantation processes at different acceleration energy levels. Hence, no change of the acceleration energy is required, thereby omitting the need for tuning cycles in which the acceleration energy of the ion implantation apparatus 900 is recalibrated for each new acceleration energy level.

Increasing the tilt angle θ also results in a smaller lower limit for the implantation depth. For example, sonic ion implanter designs may not provide a sufficient ion beam current at acceleration energies below 100 keV. By increasing the tilt angle θ to about 60°, the minimum implant depth can be reduced to a projected range significantly less than the projected range for an orthogonal implant at the same acceleration energy.

FIG. 2 shows a scanning assembly 950 including a deflection unit 955 for deflecting the ion beam 910. The ion beam 910 traverses a region between a pair of first deflection electrodes 953 deflecting the ion beam 910 along a linear first scan direction. 951. Then the ion beam 910 passes a pair of second deflection electrodes 954 deflecting the ion beam. 910 along a linear second scan direction 952 orthogonal to the drawing plane. The electric fields in the deflection unit 955 sweep the ion beam 910 across the complete main surface 701 of the semiconductor substrate 700. One of the two scan speeds may be faster than the other by a factor in a range from 10 to 100, for example. A tilt assembly 960 may tilt the substrate holder 980 by a tilt angle θ with respect to the cross-sectional plane of the beam axis 912, wherein the tilt angle θ may be continuously varied with time during the ion implantation process.

The hybrid scanning assembly 950 of FIG. 3 includes a deflection unit 955, which electrostatically scans the ion beam 910 in a linear first scan direction 951 orthogonal to the drawing plane, and a stage assembly 956, which moves the substrate holder 980 in a linear second scan direction 952 orthogonal to the first scan direction 951.

FIG. 4 relates to a method of manufacturing semiconductor devices which may use the implantation apparatus 900 of FIG. 1. An ion beam is directed onto a main surface of a semiconductor substrate 992, wherein a relative movement between the semiconductor substrate and the ion beam results in that the ion beam completely scans the main surface. During the relative movement, a tilt angle θ between a beam axis 912 of the ion beam and the normal to the main surface is changed from a first tilt angle θ1 to a second tilt angle θ2, wherein an angular span Δθ between the first tilt angle θ1 and the second tilt angle θ2 is at least 5°, e.g., at least 40° (994).

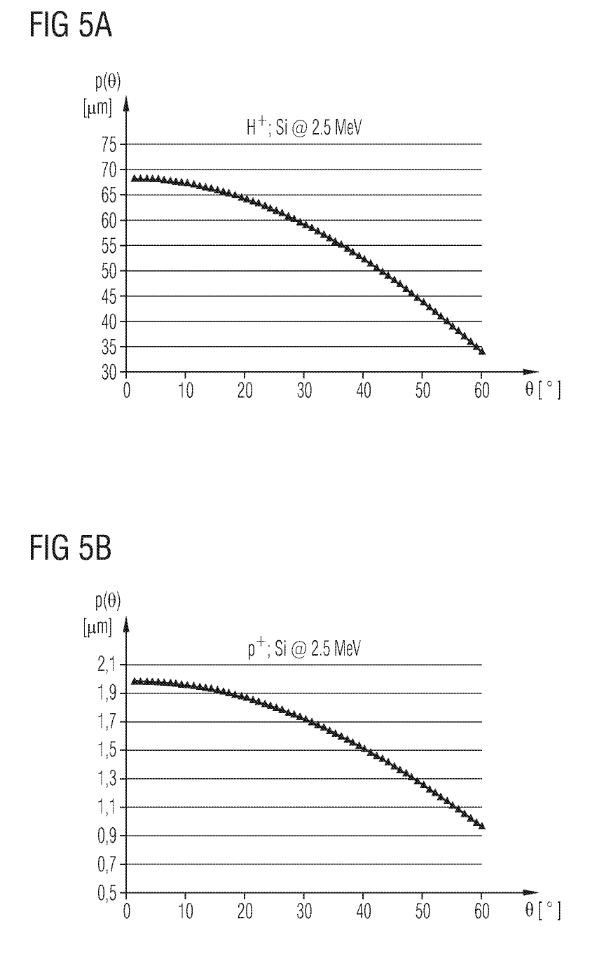

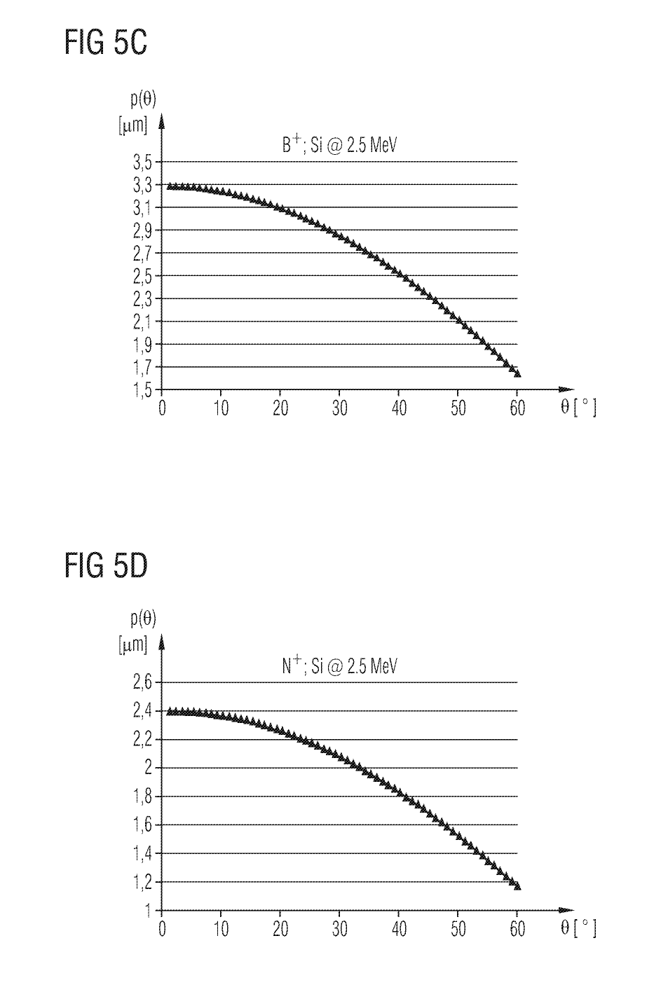

FIGS. 5A to 5D illustrate the projected range p(θ) of some ions as a function of the tilt angle θ between the normal onto a main surface and the beam axis of the ion beam.

According to FIG. 5A the projected range of protons with a kinetic energy of 2.5 MeV in silicon decreases from about 68 μm at θ=0 to about 35 μm at θ=60°.

According to FIG. 5B the projected range p(θ) of phosphorus ions in silicon at an implantation energy of 2.5 MeV drops from about 2.0 μm at θ=0 to about 1.0 μm at θ=60°.

FIG. 5C shows that the projected range p(θ) of boron ions implanted at an implantation energy of 2.5 MeV in silicon drops from about 3.3 μm at θ=0 to about 1.7 μm at θ=60°.

According to FIG. 5D the projected range p(θ) for nitrogen ions implanted at an acceleration energy of 4.0 MeV into a silicon carbide crystal drops from about 2.4 μm at θ=0 to about 1.2 μm at θ=60°.

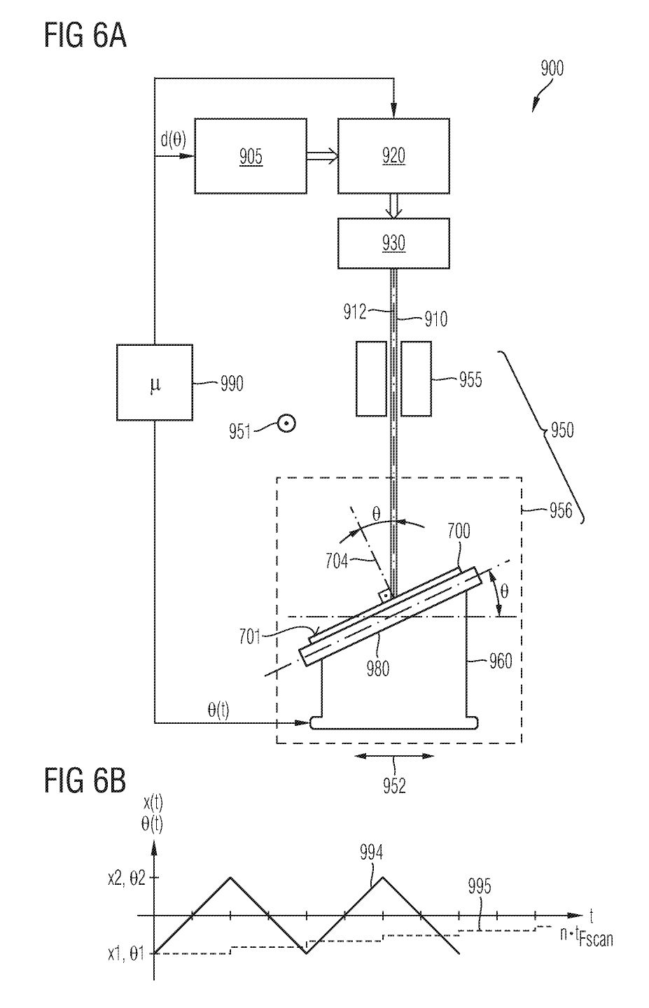

The ion implantation apparatus 900 of FIG. 6A includes a tilt assembly 960 that changes a tilt angle θ between the main surface 701 and the orthogonal cross-sectional plane of the ion beam 910 between a first tilt angle θ1 and a second tilt angle θ2 between two sweeps along the second scan direction 952.

An angular span Δθ between the first tilt angle θ1 and the second tilt angle θ2 is at least 5, for example greater than 40°, for example, 120°. The first tilt angle θ1 and the second tilt angle θ2 may be symmetric to each other with respect to the beam axis 912 with θ2=−θ1. According to another embodiment, the first tilt angle θ1 and the second tilt angle θ2 may be asymmetric with respect to the beam axis 912, e.g., θ1=0°.

In FIG. 6B line 994 shows a position x(t) of the ion beam 910 along the second scan direction 952 during one sweep between x1 and x2, wherein during one sweep between x1 and x2 the ion implantation apparatus 900 performs a plurality of sweeps along the first scan direction 951. Line 995 shows the stepwise change of θ(t) between two successive sweeps between x1 and x2.

The control unit 990 controls the tilt assembly 960 and the scanning assembly 950 such that the ion beam carries out successive sweeps at different tilt angles without intermediate tuning cycle. Such process control allows for changing, within a single implant recipe, the tilt angle θ in a way that successive sweeps at different tilt angles can directly follow each other without an intermediate tuning cycle for recalibrating the acceleration energy by applying another implant recipe, for example.

According to an embodiment the control unit 990 further controls the acceleration unit 920 to vary an acceleration of the ions between successive slow scans at different tilt angles without intermediate tuning cycle. Such process control allows for changing, within a single implant recipe, both the tilt angle θ and the acceleration energy such that scans at different tilt angles and different acceleration energies can directly follow each other without intermediate tuning cycles for recalibrating the acceleration energy.

The complete implant recipe can be calibrated as a whole and the implantation process gets along with less time-consuming tuning cycles.

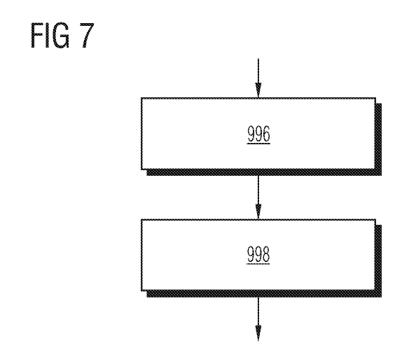

FIG. 7 relates to a method of manufacturing semiconductor devices, which may use the implantation apparatus 900 of FIG. 6A. At process feature 996, an ion beam is directed onto a main surface of a semiconductor substrate, wherein a relative movement between the semiconductor substrate and the ion beam results in that the ion beam scans the main surface along a first scan direction and a second scan direction orthogonal to the first scan direction. At process feature 998, between two scans along the second scan direction, a tilt angle θ between a beam axis 912 of the ion beam and a normal to the main surface is changed from a first tilt angle θ1 to a second tilt angle θ2, wherein an angular span Δθ between the first tilt angle θ1 and the second tilt angle θ2 is at least 5° and wherein two successive sweeps at different tilt angle directly follow one another without intermediate tuning cycle.

According to an embodiment the acceleration energy applied to ions of the ion beam is changed between two successive scans at different tilt angle and two scans at different acceleration energies follow each other without intermediate tuning cycle.

The following Figures relate to methods of forming doped structures in semiconductor devices, for example, in vertical power semiconductor devices controlling a load current between a first load electrode at a front side and a second load electrode on the back of a semiconductor die, wherein at least one of the doped structures is formed by one of the implant methods described with reference to the previous Figures.

The doped structure formed by ion implantation with continuously or stepwise changing implant angle may include drift zones, field stop zones, charge compensation zones, body regions, source regions, junction termination extensions, VLD (variation of lateral doping) regions, channel stopper regions and field rings, wherein the vertical dopant profile within the concerned doped region may be adapted to the application as regards the position of dopant concentration maxima, the position of dopant concentration minima, waviness, uniformity and slope both in silicon substrates and in SiC substrates, by way of example.

In the following Figures, the normal to a main surface 701 of the respective semiconductor substrate 700 defines a vertical direction. Directions parallel to the main surface 701 are horizontal directions.

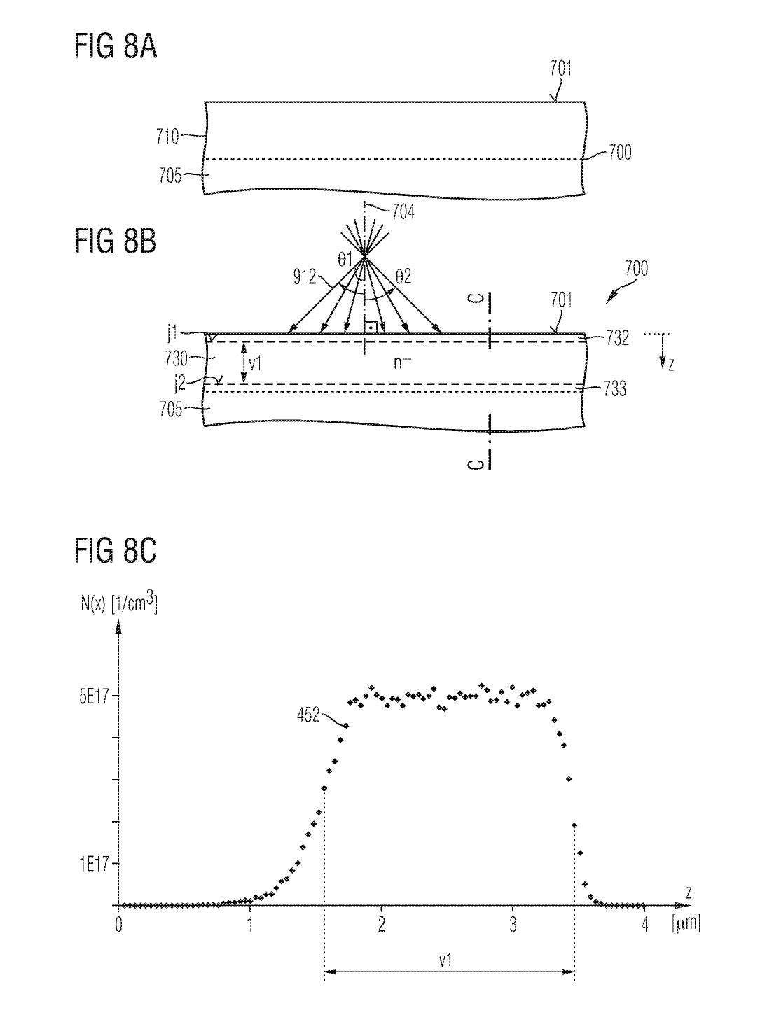

FIGS. 8A to 11B refer to the manufacture of semiconductor devices including a drift zone for accommodating a significant portion of a blocking voltage along the vertical direction.

An epitaxial layer 710 may be formed by epitaxy on a crystalline base substrate 705, wherein atoms of a deposited semiconductor material grow in registry with the crystal lattice of the base substrate 705.

FIG. 8A shows the resulting semiconductor substrate 700 including the epitaxial layer 710 at a front side of the base substrate 705. The base substrate 705 may be a crystal slice obtained from a crystal ingot by sawing. The base substrate 705 may be silicon, germanium, silicon germanium, 2H—SiC (silicon carbide of the 2H polytype), 4H—SiC, 6H—SiC or 15R—SiC, by way of example. The base substrate 705 may be heavily doped. The epitaxial layer 710 may be intrinsic or lightly doped with a background dopant concentration in a range from 10¹³ cm⁻³ to 1×10¹⁵ cm⁻³, or from 5×10¹³ cm⁻³ to 5×10¹⁴ cm⁻³.

Through a main surface 701 at the front side of the semiconductor substrate 700 dopants are implanted into at least a portion of the epitaxial layer 710, wherein an ion beam containing the dopants is directed onto the main surface 701 and a relative movement between the semiconductor substrate 700 and the ion beam 910 results in that the ion beam 910 scans the main surface 701. During the relative movement a tilt angle θ between a beam axis 912 of the ion beam 910 and the normal 704 to the main surface 701 is changed continuously or in steps from a first tilt angle θ1 to a second tilt angle θ2, wherein θ1 may be equal to −θ2 or equal to 0°, by way of example, An angular span Δθ between the first tilt angle θ1 and the second tilt angle θ2 is at least 5°, for example, at least 20°.

As illustrated in FIG. 8B the implanted dopants define a drift layer 730 completely formed within the epitaxial layer 710. The drift layer 730 forms a first horizontal junction j1 with a surface section 732 of the epitaxial layer 710 between the main surface 701 and the drift layer 730 and the drift layer 730 may form a second horizontal junction j2 with either a bottom section 733 of the first epitaxial layer 710 or with the base substrate 705. A vertical extension v1 of the drift layer 730 may be at least 1.0 μm, e.g., at least 1.5 μm.

FIG. 8C shows a schematic vertical dopant profile 152 along line C-C of FIG. 8B for in total nine implants of boron atoms at an acceleration energy of 2.5 MeV and at nine different implant angles in a range from θ1=0° to θ2=60°, with six implants at θ=0°, θ=20°, θ=28°, θ=35°, θ=40° and θ=46° at an implant dose of 1.0E13 cm⁻², one implant at θ=51° at a dose of 1.1E13 cm⁻², one implant at θ=56° at a dose of 1.2E13 cm⁻² and one implant at θ=60° at a dose of 1.4E13 cm⁻². The parameter z indicates the distance to the main surface 701.

After the implants and before any heat treatment, the resulting vertical dopant profile 452 is almost constant between z=1.8 μm and z=3.2 μm. For z<1.0 μm and for z>3.7 μm the implants have no significant impact on the background doping of the epitaxial layer 710.

The process may proceed with forming an anode region of a semiconductor diode or body regions and source zones of transistor cells in the unaffected surface section 732 of the epitaxial layer 710 and/or in a further thin layer formed by epitaxy on the epitaxial layer 710.

For semiconductor devices based on silicon carbide, the continuous or stepwise change of the implant angle may result in drift zones, which contain dopants distributed at high uniformity along the vertical direction.

For semiconductor devices based on silicon, the illustrated stepwise change of the implant angle result in that drift zones with highly uniform vertical dopant profiles can be formed at a significant lower thermal budget to be applied for a vertical diffusion of the dopants.

For silicon devices with a blocking voltage up to some hundred V the drift layer 730 may be formed with a process which is based on one single epitaxy process and one single ion implantation at continuously or stepwise changing implant angle.

For silicon devices with a blocking voltage up to some hundred V the drift layer 730 may be formed with a process including one single epitaxy process and one single ion implantation at changing implant angle as illustrated in FIGS. 8A to 8C.

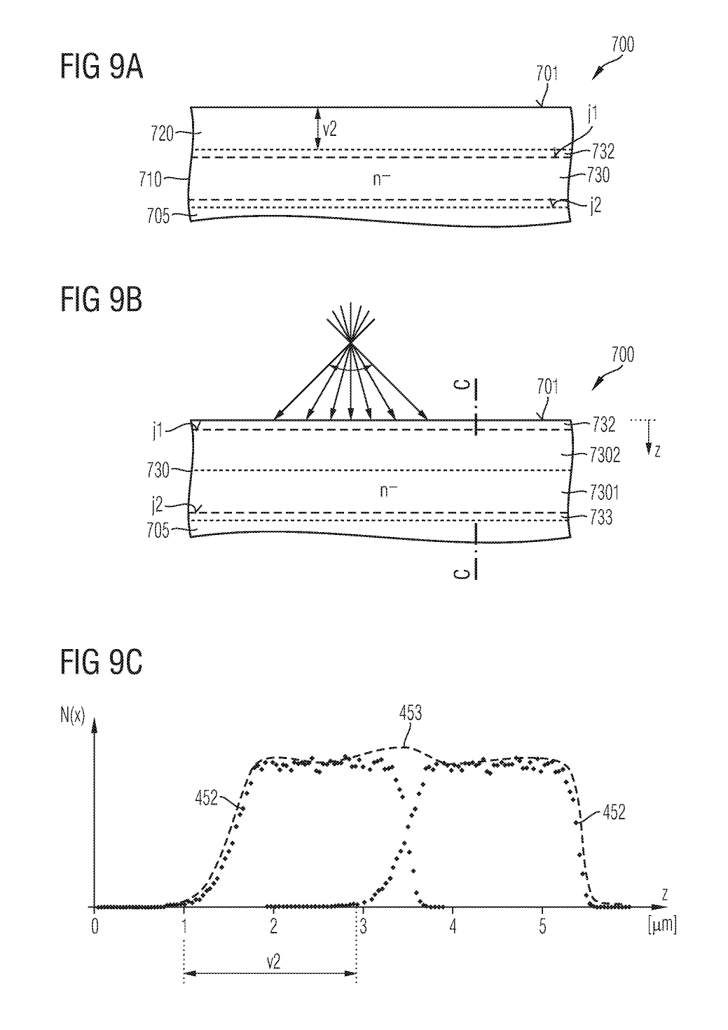

FIGS. 9A to SC refer to a drift layer 730 formed in two or more successively formed epitaxial layers. A further epitaxial layer 720 is formed on the main surface 701 of the semiconductor substrate 700 as illustrated in. FIG. 8B.

FIG. 9A shows the semiconductor substrate 700 with a second epitaxial layer 720 stacked on the first epitaxial layer 710, which in turn may be formed on a base substrate 705. The first epitaxial layer 710 includes a drift layer 730 and a surface section 732 between the second epitaxial layer 720 and the drift layer 730.

Dopants are implanted at continuously or stepwise changing implant angle in the same way or at least similar as in the ion implantation described with respect to FIG. 8B, wherein the thickness of the second epitaxial layer 720 and the implant parameters of the second ion implantation are selected such that the second ion implantation is effective also within the surface section 732 of the first epitaxial layer 710.

FIG. 9B shows an enhanced drift layer 730 resulting from both ion implantations, wherein the second ion implantation overlap to some degree with the first ion implantation along the vertical direction. The enhanced drift layer 730 includes a first partial layer 7301 formed in the first epitaxial layer 710 and a second partial layer 7302 formed in the second epitaxial layer 720. The two partial layers 7301, 7302 directly adjoin to each other and form the drift layer 730. The drift layer 730 forms a horizontal first junction j1 close to the main surface 701 and a horizontal second junction j2 within either the bottom section 733 of the first epitaxial layer 710 or with the base substrate 705.

FIG. 9, shows the vertical dopant profile 453 for the drift layer 730 of FIG. 9B. According to the illustrated embodiment, the vertical dopant profile 453 results from the superposition of two identical vertical dopant profiles 452 as illustrated in FIG. 8C and shifted to each other by the thickness v2 of the second epitaxial layer. According to other embodiments the implant parameters of the second implant may be adjusted in a way that even in a transition region where the two vertical dopant profiles 452 overlap the vertical dopant profile 453 is as flat as on both sides of the transition region.

The sequence of epitaxial growth and ion implantation into the epitaxial layer at changing implant angles may be repeated several times to form a drift layer with a desired target thickness suitable for the target blocking voltage.

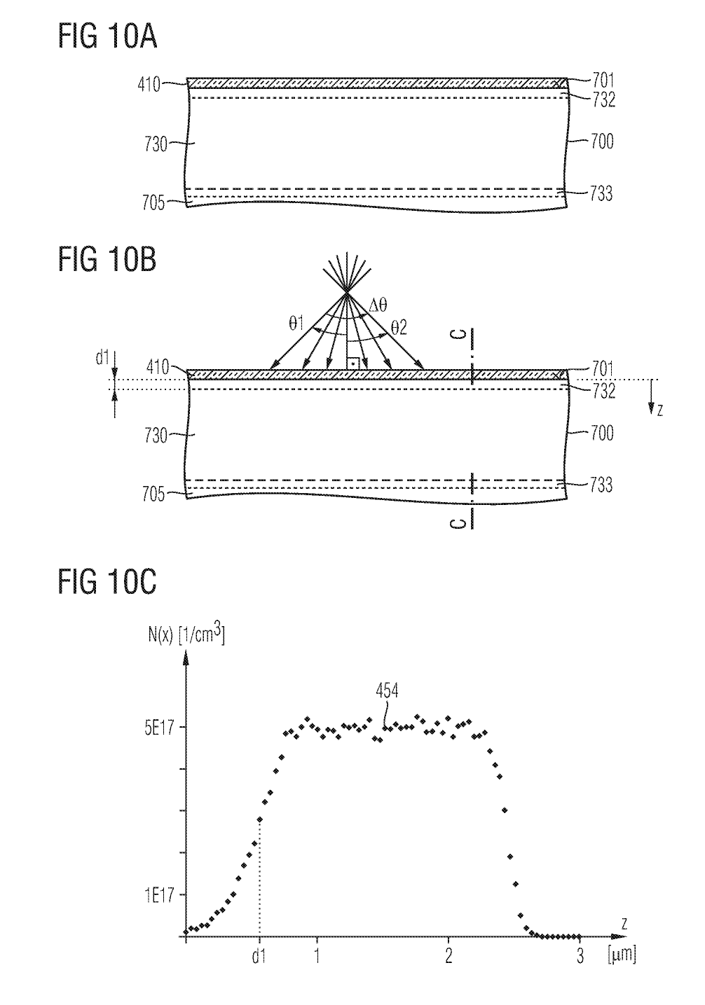

FIGS. 10A to 10C relate to an embodiment facilitating the formation of a doped layer at a low distance to the main surface 701. The doped layer may be a drift layer 730, by way of example. An absorber layer 410 is formed on the main surface 701 of a semiconductor substrate 700.

FIG. 10A shows the absorber layer 410 covering the main surface 701 of the semiconductor substrate 700, which includes a first epitaxial layer 710 formed on a base substrate 705. The absorber layer 410 may be a layer from a photoresist or a hard mask, for example, a layer from silicon oxide.

As illustrated in FIG. 10B dopants are implanted into the semiconductor substrate 700 through the absorber layer 410 by using one of the above described implant methods. The absorber layer 410 attenuates the ions and reduces the projected range.

FIG. 10C refers to a sequence of implants as described with reference to FIGS. 8B and 8C. The resulting vertical dopant profile 454 is mainly similar to the vertical dopant profile 452 of FIG. 8C but shifted to lower values of z and closer to the main surface 701 such that the vertical dopant profile 454 is approximately uniform for a range of z between 0.9 μm to 2.5 μm.

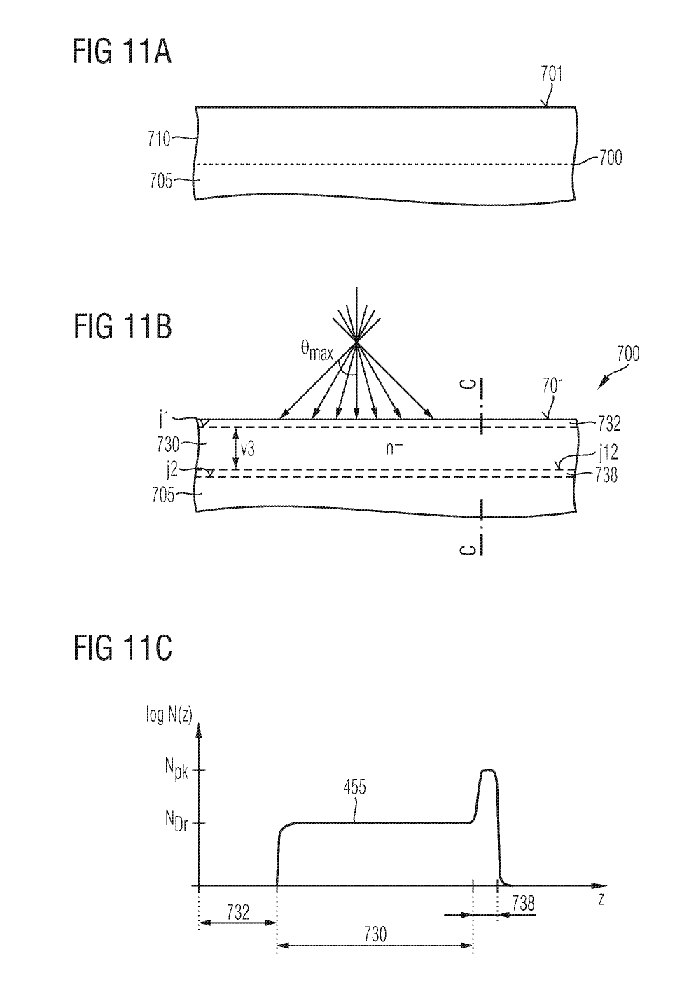

FIGS. 11A to 11C refer to a method of controlling ion implantation at continuously or stepwise changing implant angle in combination with a significant change of at least the implant dose for the integrated formation of a drift layer 730 and a field stop or charge compensation layer 738.

FIG. 11A shows a semiconductor substrate 700 including an epitaxial layer 710 formed on a base substrate 705 as described with reference to FIG. 8A. Ion implantation is performed at stepwise or continuously changing the implant angle during processing of a single implant recipe as discussed above. Other than in the embodiment of FIG. 8B, θ(t) and at least the implant dose D(θ) are controlled to form, in addition to a drift layer 730 with approximately uniform vertical dopant profile, a field stop or charge compensation layer 738 in a portion of the first epitaxial layer 710 between the drift layer 730 and the base substrate 705, wherein a peak dopant concentration Npk in the field stop or charge compensation layer 738 is at least twice, for example at least ten times a mean dopant concentration NDr in the drift layer 730.

FIG. 11C shows the vertical dopant profile 455 along line C-C of FIG. 11B. A vertical extension v3 of the drift layer may be in a range from 1 μm to 70 μm, for example in a range from 1 μm to 3 μm. Since both the drift layer 730 and the field stop or charge compensation layer 738 are formed from the same side, a distance between the first junction j1 and the field stop or charge compensation layer 738 is well-defined and, other than in case of implanting the field stop or charge compensation layer 738 from the back, does not depend from the thickness of an epitaxial layer, wherein the thickness of an epitaxial layer is subject to fluctuations caused by process variations inherent for the epitaxy process.

The field stop layer or charge compensation layer 738 may be designed to be effective as field stop or to increase avalanche ruggedness and radiation hardness of a semiconductor device obtained from the semiconductor substrate 700.

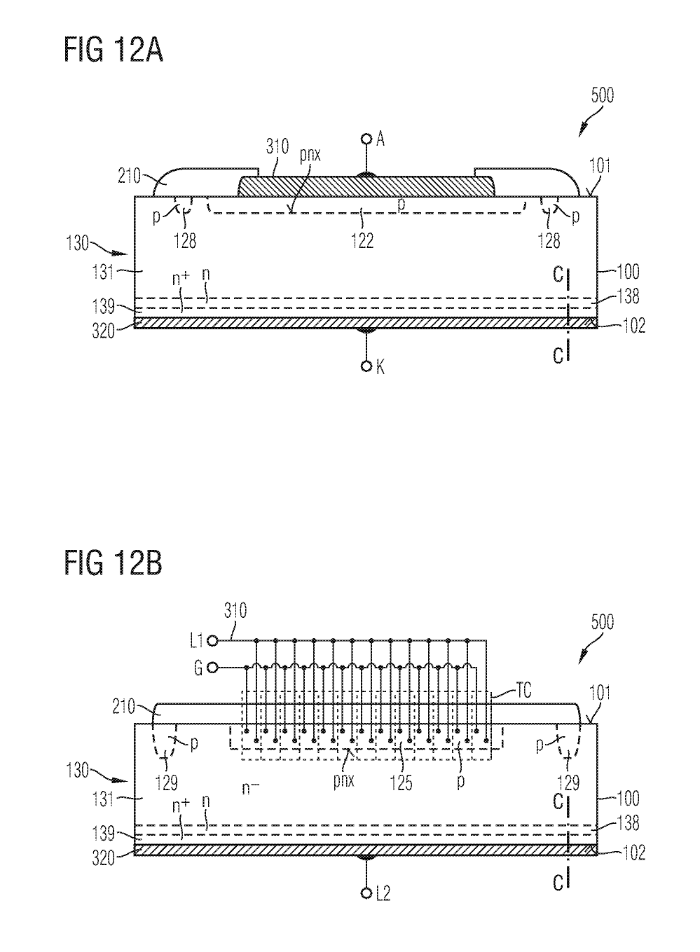

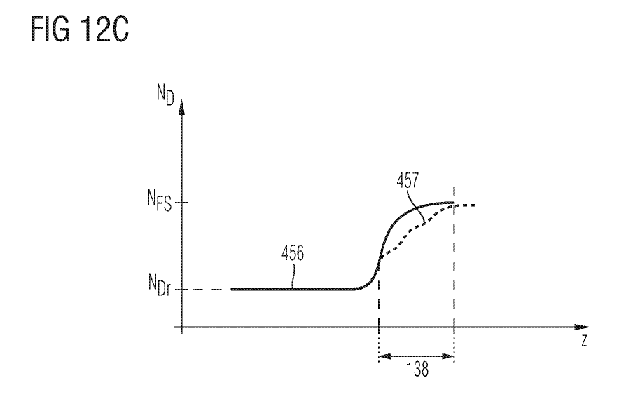

FIGS. 12A and 12B show vertical cross-sections of semiconductor devices 500 which may be obtained from one of the methods described in detail with respect to FIGS. 8A to 11C, wherein any of the illustrated doped structures may result from ion implantation including stepwise or continuous change of the implant angle during processing of a single implant recipe. Vertical cross-sections orthogonal to the illustrated cross-sections may widely correspond to or may be qualitatively identical to the illustrated cross-sections.

The semiconductor device 500 of FIG. 12A is a power semiconductor diode based on a semiconductor portion 100, which may be a crystal form 4H—SiC, 2H—SiC, 6H—SiC or 15R—SiC, silicon, germanium or silicon germanium, by way of example. A first surface 101 of the semiconductor portion 100 at the front side is parallel to an opposite second surface 102 on the back. A drift structure 130 directly adjoins the second surface 102. The drift structure 130 may include a lightly doped drift zone 131 as well as a heavily doped contact portion 139 between the drift zone 131 and the second surface 102, wherein the contact portion 139 has the same conductivity type as the drift zone 131.

The drift structure 130 may be electrically connected or coupled to a second load electrode 320 through a low-resistive contact. For example, a dopant concentration in the contact portion 139 along the second surface 102 is sufficiently high to form a low-resistive contact with the second load electrode 320 that directly adjoins the second surface 102. The second load electrode 320 forms or is electrically connected or coupled to a cathode terminal K of the semiconductor diode.

The drift zone 131 results from a drift layer formed by ion implantation at continuously or stepwise changing tilt angle as described above. A net dopant concentration in the drift zone 131 may be in a range from 1E14 cm⁻³ to 3E16 cm⁻³ in case the semiconductor portion 100 is based on silicon carbide.

The drift structure 130 may include further doped regions between the drift zone 131 and the first surface 101 and between the drift zone 131 and the second surface 102. The drift zone 131 may form a horizontal pn junction pnx with an anode region 122 that is formed between the first surface 101 and the drift structure 130. A first load electrode 310 directly adjoins the anode region 122 and may form or may be electrically connected or coupled to an anode terminal A. A dielectric layer 210 may cover sidewalls of the first load electrode 310.

Conventionally, a dopant concentration in the drift zone 131 results from in-situ doping during the epitaxial growth of an epitaxial layer in which the drift zone 131 is formed. The process of in-situ doping results in comparatively large deviations of the total amount of dopants incorporated in the growing crystal and in fluctuations of the dopant concentration within the same semiconductor device, among semiconductor devices obtained from the same semiconductor substrate and among semiconductor devices obtained from different semiconductor substrates.

By contrast, ion implantation with stepwise or continuous change of the tilt angle as described above facilitates tighter tolerances for the total amount, of dopant atoms in the drift zone 131 and more precisely defines the distribution of the dopant atoms in the drift zone 131 along the vertical direction.

Instead of or in addition to the drift zone 131 any of the other doped structures may result from ion implantation using stepwise or continuous change of the implant angle, e.g., the anode region 122, a field stop zone 137 or junction termination structures 128 extending in a peripheral region outside the anode region 122 into from the first surface 101 into the drift zone 131 and forming pn junctions with the drift zone 131.

FIG. 12B is a semiconductor device 500 including transistor cells TC. The semiconductor device 500 may be, for example, an IGFET (insulated gate field effect transistor), an IGBT (insulated gate bipolar transistor) or an MCD (MOS controlled diode). As regards details of the semiconductor portion 100 and the drift structure 130 reference is made to the description of the semiconductor diode in FIG. 12A.

Instead of an anode region, the semiconductor device 500 of FIG. 12B includes transistor cells TC, wherein in each transistor cell TC a body region 120 separates a source zone from the drift structure 130. The body regions 120 form first transistor pn junctions, which correspond to the pn junctions pnx of FIG. 12A, with the drift structure 130, e.g., with the drift zone 131. The body regions 120 further form second transistor pn junctions with the source zones.

A first load electrode 310 electrically connected to the body regions 120 and the source regions of the transistor cells TC may form or may be electrically connected or coupled to a first load terminal L1, which may be an anode terminal of an MCD, a source terminal of an IGFET or an emitter terminal of an IGBT.

A second load electrode 320 electrically connected to the contact portion 139 may form or may be electrically connected or coupled to a second load terminal L2, which may be a cathode terminal of an MCD, a drain terminal of an IGFET or a collector terminal of an IGET.

The transistor cells IC may be transistor cells with planar gate electrodes or with trench gate electrodes, wherein the trench gate electrodes may control a lateral channel or a vertical channel. According to an embodiment, the transistor cells IC are n-channel FET cells with p-doped body regions 120, n-doped source zones and an n-doped drift zone 131.

Instead of or in addition to the drift zone 131 any of the other doped structures may result from ion implantation using stepwise or continuously changing implant angle, e.g., the anode region 122 or junction termination structures 128 extending in a peripheral region outside the anode region 122 into from the first surface 101 into the drift zone 131 and forming pn junctions with the drift zone 131.

Instead of or in addition to the drift zone 131, any of the other doped structures may result from ion implantation using stepwise or continuously changing implant angle, e.g., the body regions 125, the source regions, channel stoppers or deep field rings 129 extending in a peripheral region between the transistor cells IC and an outer surface from the first surface 101 into the drift zone 131 and forming pn junctions with the drift zone 131.

In the illustrated embodiment the semiconductor devices 500 of FIGS. 12A and 12B include a field stop or charge compensation zone 138 obtained from the field stop or charge compensation layer 738 of FIG. 11B. According to other embodiments, the semiconductor devices 500 may include a field stop or charge compensation zone 138 formed independently from the drift zone 131.

FIG. 12C illustrates a vertical dopant profile 456 of the field stop or charge compensation zones 138 of the semiconductor devices of FIG. 12A or FIG. 12B, wherein the field stop or charge compensation zones 138 are formed by proton implantation from the rear side at continuously or stepwise changing implant angle and at an acceleration energy depending on the implant angle. A heat treatment between 380° C and 420° C. for typically at least 30 minutes and less than 10 hours may activate hydrogen-related donors.

The vertical dopant profile 456 may approximate a Gaussian distribution with low waviness. In the alternative, a vertical dopant profile 457 may include two or more smooth steps.

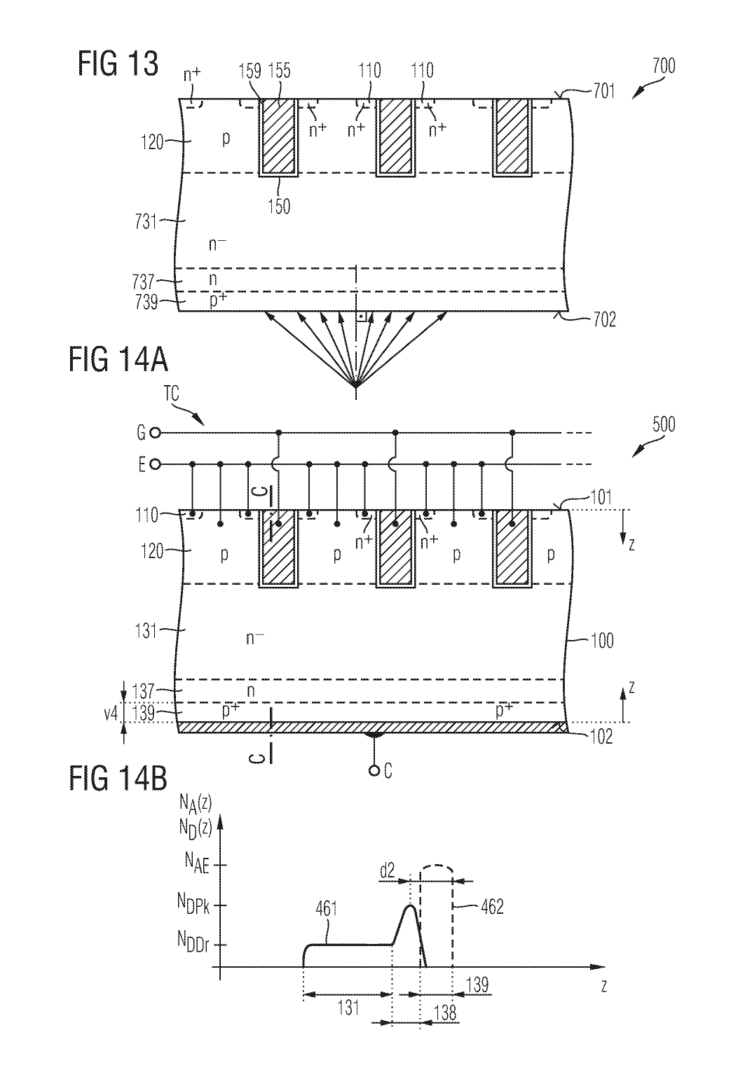

FIG. 13 refers to the formation of a deep emitter layer at the rear side of an IGBT, e.g., a reverse-blocking IGBT.

In a semiconductor substrate 700 including a drift zone layer 731 transistor cells TC are formed at the front side between a main surface 701 and the drift zone layer 731, wherein the transistor cells TC include gate electrodes 155 that may extend between body regions 120 from the main surface 701 into the drift zone layer 731. The trench gate structures 150 may include a conductive gate electrode 155 and a gate dielectric 159 separating the gate electrode 155 from the body regions 120. Source zones 110 directly adjoin at least one sidewall of the trench gate structures 150. The body regions 120 separate the source zones 110 from the drift zone layer 731, form first pn junctions pn1 with the drift zone layer 731 and form second pn junctions pn2 with the source zones 110.

Between the drift zone layer 731 and a rear side surface 702 opposite to the main surface 701 a field stop layer 737 may be formed, wherein a mean net dopant concentration in the field stop layer 737 is at least twice, for example at least ten times a mean dopant concentration in the drift zone layer 731. The field stop layer 737 may be spaced from the rear side surface 702 or may directly adjoin the rear side surface 702.

Dopants with the conductivity type opposite to the conductivity type of the drift zone layer 731 are implanted from the rear side through the rear side surface 702 to form an emitter layer 739, wherein during ion implantation an implant angle is stepwise or continuously changed as discussed above. The process may proceed with forming a rear side metallization and dicing the semiconductor substrate 700 along scribe lines to obtain a plurality of identical semiconductor dies.

FIG. 14A shows a semiconductor device 500, which may be a reverse blocking IGBT, obtained from the semiconductor substrate 700 of FIG. 13. The body regions 120 and the source zones 110 are electrically connected or coupled to a second load electrode 320 which forms or which may be electrically connected to an emitter terminal E. A drift zone 131 is formed from a portion of the drift zone layer 731 of FIG. 13 and a field stop zone 137 is formed from a portion of the field stop layer 737 of FIG. 13.

A heavily doped contact portion 139 includes a hole emitter on the rear side of the semiconductor device 500, wherein the hole emitter results from the emitter layer 739 of FIG. 13 and from a stepwise or continuously changing implant angle. A vertical extension v4 of the emitter layer 739 may be in a range from 100 nm to 3 μm or from 200 nm to 2 μm or even from 250 nm to 1 μm. According to an embodiment the hole emitter is not completely annealed and contains a comparatively large number of crystal defects and interstitial dopant atoms such that hole emitter efficiency is reduced.

In FIG. 14B line 461 indicates the vertical dopant profile for donors and line 462 the vertical dopant profile for acceptors. The donor concentration. N_{A}(z) may have one or more peaks. A distance d2 between the peak closest to the second surface 102 and the second surface may be in a range from 500 nm to 10 μm, or from 1 μm to 8 μm, or from 2 μm to 5 μm, for example to the pn junction formed between the field stop zone 137 and the contact portion 139. A small distance d2 between the peak of donor concentration N_{A}(z) and the pn junction and the not completely annealed emitter layer allow for a further degree of freedom for designing the saturation voltage V_{CSAT} and short circuit ruggedness.

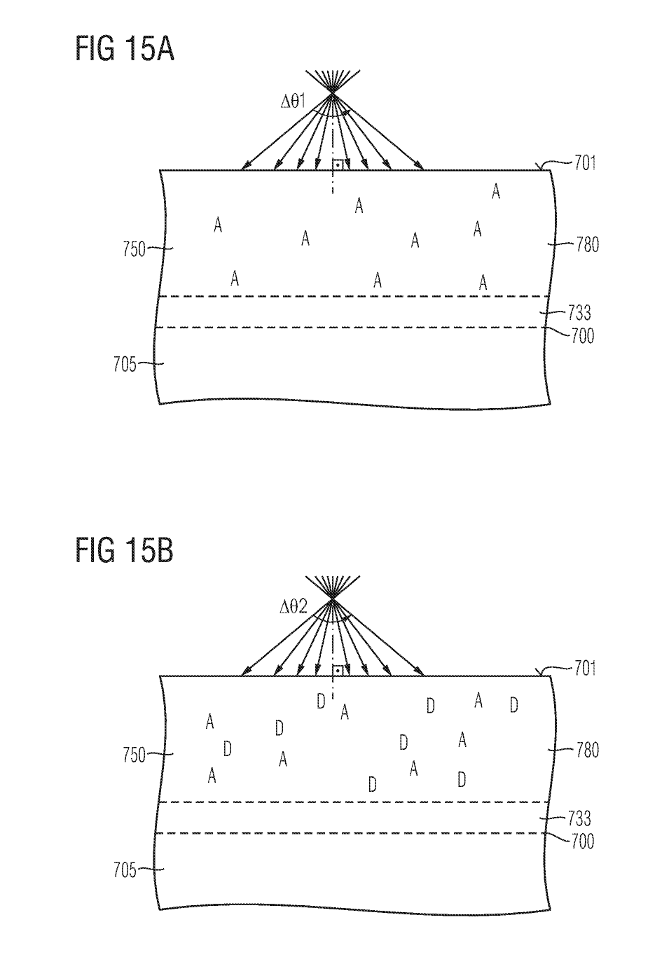

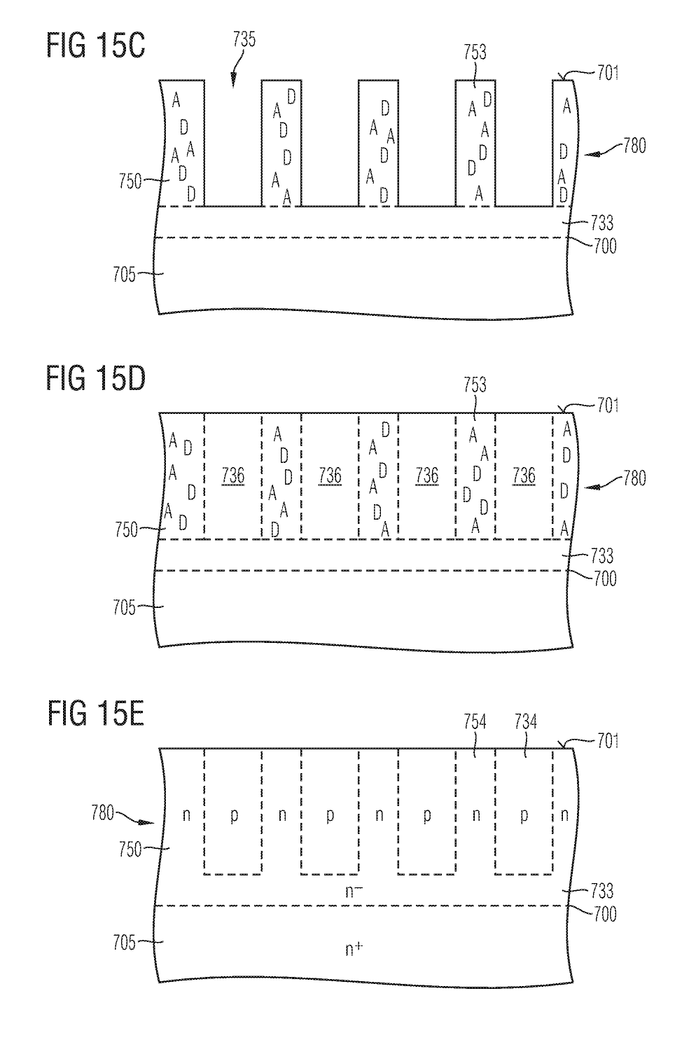

FIG. 15A to 15E relate to a method of forming a superjunction structure by using ion implantation at stepwise or continuously changing implant angle.

A first ion implantation with continuously or stepwise changing implant angle as described above may introduce acceptor ions into a portion of a lightly doped layer 750 in a semiconductor substrate 700.

FIG. 15A shows the semiconductor substrate 700 and a superjunction layer 780 containing the implanted acceptors. The lightly doped layer 750 may be an epitaxial layer formed on a heavily doped base substrate 705. An unaffected bottom section 733 of the lightly doped layer 750 may not include acceptors to a significant degree and may separate the superjunction layer 780 from a heavily doped base substrate 705.

A second ion implantation with continuously or stepwise changing implant angle as described above introduces donors into the superjunction layer 780, wherein an angular span Δθ2 of the second ion implantation may be equal to or may be different from an angular span Δθ1 of the first implant.

As illustrated in FIG. 15B, after the second ion implantation the superjunction layer 780 includes both acceptors and donors. Trenches 735 are etched from the front side into the semiconductor substrate 700.

According to FIG. 15C the trenches 735 may extend from the main surface 701 into the superjunction layer 780. The Trenches 735 may extend through the superjunction layer 780, wherein the trenches 735 may expose the bottom section 733 of the drift layer 730. Remnant portions of the semiconductor substrate 700 between the trenches 735 form columnar structures 753. A deposition process, e.g., an epitaxy process may fill the trenches 735 with crystalline semiconductor material 736.

FIG. 15D shows the semiconductor material 736 filling the trenches 735 of FIG. 15G. The semiconductor material 736 may be intrinsic or may be lightly doped with a mean dopant concentration less than 1E13 cm⁻³, or less than 5E13 cm⁻³. A heating treatment diffuses the acceptors and donors from the columnar structures 753 into the semiconductor material 736. Different diffusion coefficients for the acceptors and donors result in a partial separation of the acceptors and donors such that after the heat treatment the slower ones of the acceptors and donors exceed the faster ones in number in the columnar structures 753 and the faster ones exceed the slower ones in number in the semiconductor material 736.

FIG. 15E shows the resulting superjunction structure with p-type columns 734 resulting from a local excess of acceptors and n-type columns 754 resulting from a local excess of donors. Since the original distribution of the acceptors and donors and their number is given by a precisely controllable ion implantation process, manufacturing yield is high and the fluctuations of such device parameters, which depend on details of dopant profiles and dopant concentration in the superjunction structure, are reduced. The varying implant angle provides a highly uniform dopant profile along the vertical direction and waviness of the vertical dopant profile in the p-type columns 734 and in the n-type columns 754 is low.

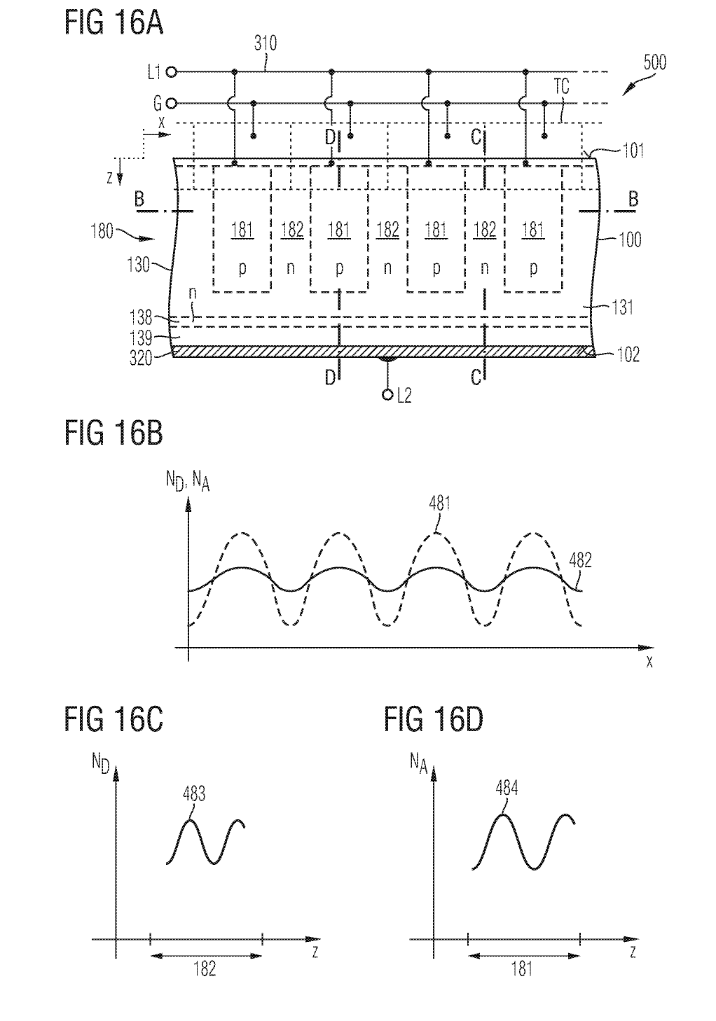

FIG. 16A shows a semiconductor device 500 with a drift structure 130 including a superjunction structure 180, which may partly or completely substitute a conventional drift zone. The superjunction structure 180 includes p-doped columns 181 that may result from the p-type columns 734 of FIG. 15E and further includes n-doped columns 182 that may be formed from the n-type columns 754 of FIG. 15E. The semiconductor device 500 may be an MCD, a MOSFET or an IGBT, by way of example. For further details reference is made to the semiconductor device of FIG. 12B.

According to another embodiment, the superjunction structure 180 may be formed by two successive masked ion implantations at stepwise or continuously changing implant angle. Ion implantation of the donors uses a first implant mask with first mask openings and ion implantation of the acceptors uses a second mask with second mask openings. The first and second mask openings may be stripe-shaped. With respect, to the semiconductor substrate, the second mask openings are formed between the first mask openings.

FIG. 16B shows a horizontal donor profile 481 and a horizontal acceptor profile 482 in the superjunction structure 180 of FIG. 16A.

FIG. 16C shows a vertical donor profile 483 and FIG. 16D a vertical acceptor profile 484 in the superjunction structure 180 of FIG. 16A.

Within the n-doped columns 182 a ratio between local maxima and local minima of the vertical donor profile 483 may be in a range from 1.03 to 20, or from 1.05 to 5, or from 1.1 to 3, for example. Within the p-doped columns 181 a ratio between local maxima and local minima of the vertical acceptor profile 484 may be in a range from 1.03 to 20, or from 1.05 to 5, or from 1.1 to 3, for example.

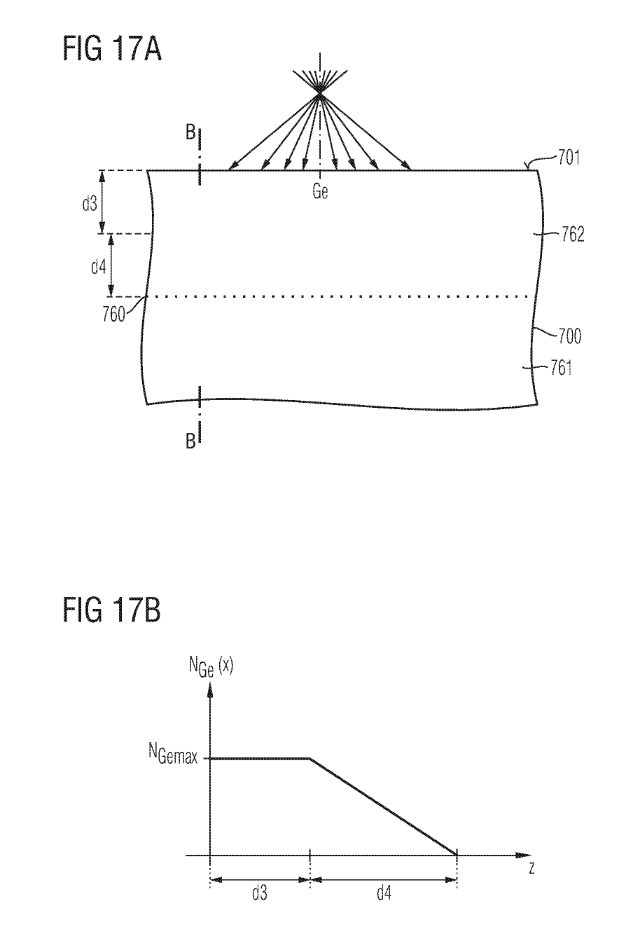

FIGS. 17A to 17C refer to the formation of germanium doped layers in semiconductor substrates based on silicon.

According to FIG. 17A germanium is ion implanted through a main surface 701 at a front side of a semiconductor substrate 700 of silicon. The semiconductor substrate 700 may include a lightly doped or heavily doped silicon layer 760. The germanium ions are implanted into a first substrate section 762 directly adjoining the main surface 701, wherein the implant angle changes continuously or in steps. A second substrate section 761 may remain unaffected.

FIG. 17B shows the vertical germanium profile 471 along line B-B of FIG. 17A after ion implantation. The germanium concentration NGe(z) may be equal to a maximum value NGEmax across a distance d3, wherein the distance d3 may be at least 100 nm, for example at least 500 nm. The area of high germanium content may directly adjoin the main surface 701. Beyond the distance d3, the germanium content may steadily decrease across a vertical distance d4, which may be at least 100 nm, for example at least 500 nm.

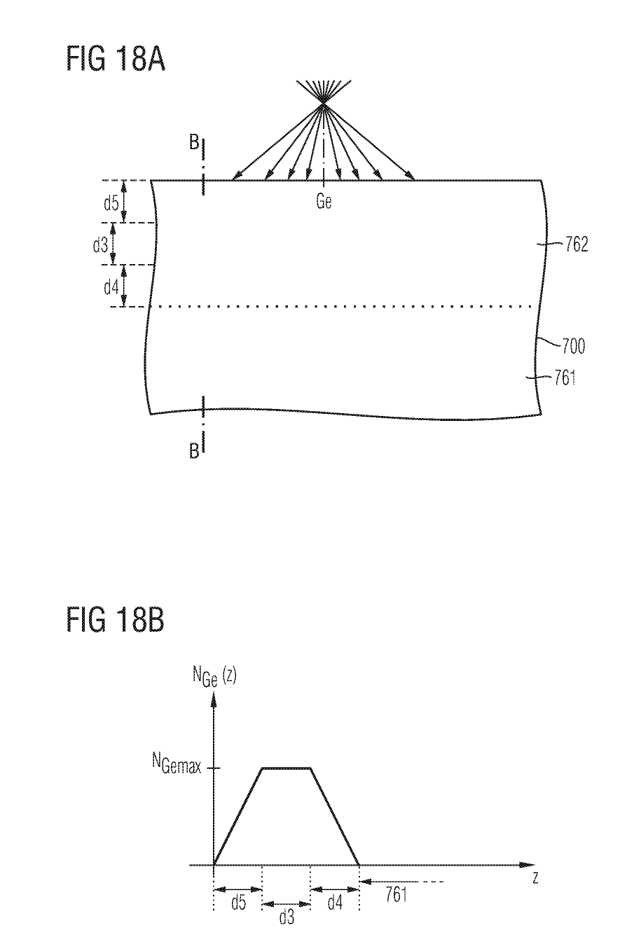

In FIGS. 18A to 18B the implant forms a zone, in which the germanium content steadily increases across a distance d5, wherein the distance d5 may be at least 100 nm, for example at least 500 nm or equal to d4. A germanium concentration along and close to the main surface 701 may be zero or not significant.

The germanium containing first substrate section 762 relaxes mechanical stress which may be induced by a layer formed, e.g., by epitaxy on the main surface 701 and differing significantly from the second substrate section 761 as regards dopant content.

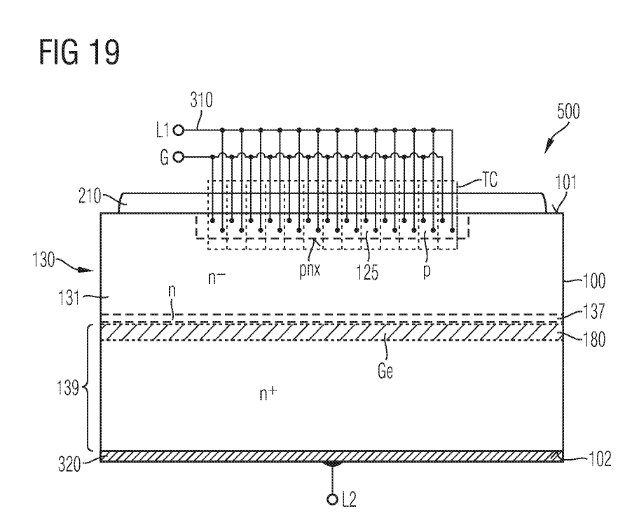

FIG. 19 shows a semiconductor device 500 with a drift structure 130 including a stress-relaxation layer 190. The stress-relaxation layer 190 is formed from the germanium-containing first substrate section 762 of FIG. 17A or FIG. 18A. The semiconductor device 500 may be a MOSFET, by way of example. For further details reference is made to the semiconductor device of FIG. 12B.

The stress-relaxation layer 190 is formed between or may overlap with at least one of the heavily doped contact portion 139, the field stop zone 137 and the drift zone 131. The germanium-containing layer reduces the mechanical strain between the heavily-doped contact portion at one site and the more lightly-doped field stop zone 137 and drift zone 131 at the other side.

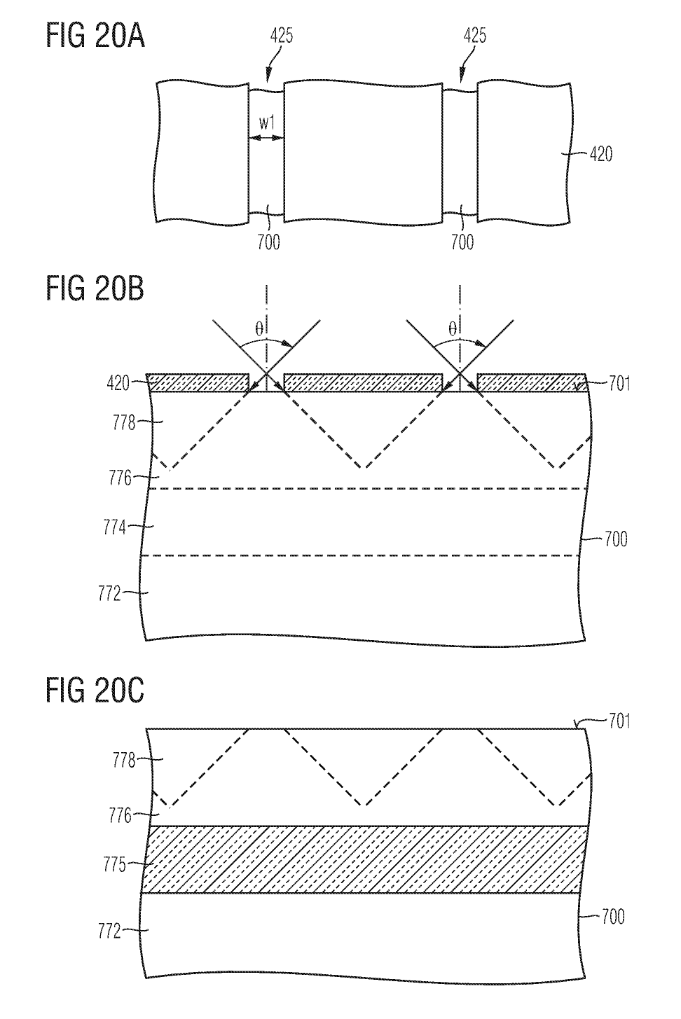

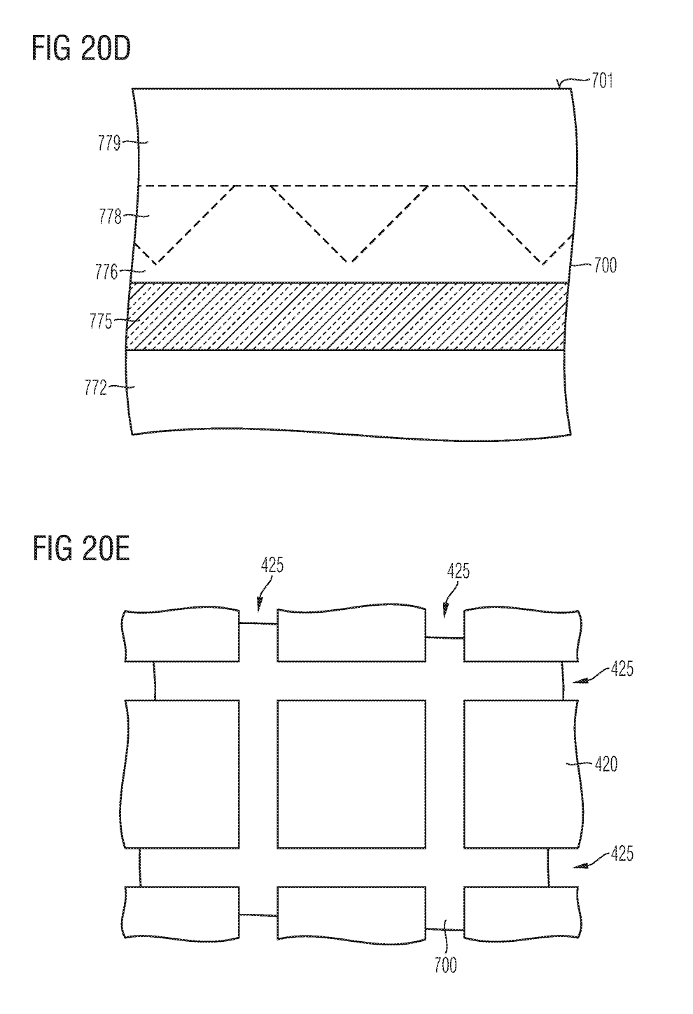

FIGS. 20A to 20E refer to the formation of a buried oxide layer using an SIMOX (separation by implantation of oxygen) approach.

A mask layer is deposited on a main surface 701 of a semiconductor substrate 700 and patterned by photolithography to form an implant mask 420 with mask openings 425 exposing the semiconductor substrate 700.

According to the embodiment of FIG. 20A the implant mask 420 includes stripe-shaped mask openings 425 exposing the main surface 701. A width of and a pitch between some or all of the mask openings 425 may be adjusted depending on the tilt angle of the oxygen ion implantation for enabling a continuous oxide layer between respective neighboring mask openings. In some areas, the oxide layer may also be omitted. The implant mask 420 may consist of or include a silicon nitride layer, a silicon oxide layer, a silicon oxynitride layer, a photoresist layer or a combination thereof, by way of example. Ion implantation at stepwise or continuously changing implant angle introduces oxygen atoms through the stripe-shaped mask openings 425, wherein the oxygen ions come to rest in an oxygen containing zone 774 around the projected range, which may sweep along the vertical direction with the implant angle.

FIG. 20B shows the oxygen containing zone 774 formed at a distance to the main surface 701. Between the main surface 701 and the oxygen containing zone 774 the implanted oxygen ions pass first regions 776, in which the passing oxygen ions damage to some degree the crystal lattice of the semiconductor substrate 700. Tapering second regions 778 below the implant mask 420 remain unaffected.

The implant mask 420 may be removed and a heat treatment forms a buried silicon oxide layer 775 from the oxygen containing zone 774 of FIG. 19B.

FIG. 20C shows the buried silicon oxide layer 775 and the main surface 701 exposed by removal of the implant mask 420. An epitaxial layer 779 may be formed on the main surface 701.

FIG. 20D shows the epitaxial layer 779. Since in the second regions 778 the silicon crystal is undamaged, the epitaxial layer 779 grows at high crystal quality and may laterally overgrow the damaged first regions 776, which lateral width is defined by the width w1 of the stripe-shaped mask openings 425.

FIG. 20E shows another example for an implant mask 420 including a grid-like mask opening 425. The oxygen implant may include two periods with the semiconductor substrate 700 rotated by 90° in the horizontal plane between the first and the second period.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An implantation apparatus, comprising:
a scanning assembly configured to effect a relative movement between an ion beam and a semiconductor substrate along a first scan direction and along a second scan direction orthogonal to the first scan direction;
a tilt assembly configured to change a tilt angle θ between a beam axis of the ion beam and a normal to a main surface of the semiconductor substrate from a first tilt angle θ1 to a second tilt angle θ2, wherein an angular span Δθ between the first tilt angle θ1 and the second tilt angle θ2 is at least 5°; and
a control unit configured to control the tilt assembly to continuously change the tilt angle θ during the relative movement between the ion beam and the semiconductor substrate.

2. The implantation apparatus of claim 1, wherein the scanning assembly comprises a deflection unit configured to deflect the ion beam along the first scan direction and along the second scan direction.

3. The implantation apparatus of claim 2, wherein a scanning speed along the first scan direction is larger than a scanning speed along the second direction, and wherein the control unit is configured to change the tilt angle θ by the angular span Δθ during a single ion implantation process that includes a plurality of up- and down-sweeps of the ion beam along the second scan direction.

4. The implantation apparatus of claim 1, wherein the scanning assembly comprises: a deflection unit configured to deflect the ion beam along the first scan direction and a stage assembly configured to move the semiconductor substrate along the second scan direction.

5. The implantation apparatus of claim 1, wherein the control unit is configured to change a dose of the ion beam as a function of the tilt angle θ.

6. The implantation apparatus of claim 1, further comprising an ion source configured to generate the ion beam from at least one of nitrogen, aluminum, arsenic, phosphorus, boron, selenium, germanium, oxygen, and sulfur ions.

7. A method of manufacturing semiconductor devices, the method comprising:
directing an ion beam onto a main surface of a semiconductor substrate, wherein a relative movement between the semiconductor substrate and the ion beam results that the ion beam scans the main surface; and
continuously changing, during the relative movement, a tilt angle θ between a beam axis of the ion beam and a normal to the main surface from a first tilt angle θ1 to a second tilt angle θ2, wherein an angular span Δθ between the first tilt angle θ1 and the second tilt angle θ2 is at least 5°.

8. The method of claim 7, further comprising:
deflecting the ion beam along a horizontal first scan direction and along a horizontal second scan direction tilted to the first scan direction.

9. The method of claim 7, further comprising:
deflecting the ion beam along a horizontal first scan direction; and
moving the semiconductor substrate along a horizontal second scan direction titled to the first scan direction.

10. The method of claim 8, wherein a scanning speed along the first scan direction is set larger than a scanning speed along the second scan direction, and wherein the tilt angle θ is varied over the angular span Δθ during a single ion implantation process that includes a plurality of up- and down-sweeps of the ion beam along the second scan direction.

11. The method of claim 7, further comprising:
controlling an implant dose D(θ,t) of the ion beam as a function of the tilt angle θ(t).

12. The method of claim 11, wherein D(θ,t)=D0/cos(θ(t)) with D0 equal to the implant dose at θ=0°.

13. The method of claim 7, wherein ions implanted by the ion beam form a doped layer extending from a first horizontal junction parallel to the main surface to a second horizontal junction parallel to the main surface.

14. The method of claim 13, wherein the doped layer comprises a drift layer and the first horizontal junction comprises a pn junction.

15. The method of claim 13, wherein the doped layer comprises a field stop or charge compensation layer.

16. The method of claim 13, wherein the doped layer forms a hole emitter layer of an insulated gate bipolar transistor.

17. The method of claim 13, wherein the implanted ions comprise donors and acceptors with different diffusion coefficients, wherein trenches extending into the drift layer are filled with a semiconductor material, and wherein a heat treatment diffuses at least one of the donors and acceptors into the semiconductor material.

18. The method of claim 13, wherein the semiconductor substrate comprises a silicon crystal and the doped layer is formed by ion implantation of germanium.

19. The method of claim 7, wherein the semiconductor substrate comprises a silicon carbide crystal.

20. The method of claim 7, further comprising:
forming, before directing the ion beam onto the semiconductor substrate, an implant mask on the main surface.

21. The method of claim 20, wherein the ion beam comprises oxygen ions, and wherein portions of the semiconductor substrate containing implanted oxygen are transformed into a buried silicon oxide layer, the method further comprising:
growing an epitaxial layer on the main surface.

22. An implantation apparatus, comprising:
a scanning assembly configured to effect a relative movement between an ion beam and a semiconductor substrate along a first scan direction and along a second scan direction orthogonal to the first scan direction;
a tilt assembly configured to change a tilt angle θ between a beam axis of the ion beam and a normal to a main surface of the semiconductor substrate from a first tilt, angle θ1 to a second tilt angle θ2, wherein an angular span Δθ between the first tilt angle θ1 and the second tilt angle θ2 is at least 5°; and
a control unit configured to control the tilt assembly and the scanning assembly during a single ion implantation process to perform successive sweeps along the second scan direction at different tilt angles.

23. The implantation apparatus of claim 22, further comprising as acceleration unit configured to accelerate ions of the ion beam, wherein the control unit is further configured to control the acceleration unit during a single ion implantation process to vary an acceleration of the ions between successive sweeps along the second scan direction at different tilt angles.
